(19) United States
(12) Patent Application Publication
(10) Pub. No.: US 2023/0393220 A1
(43) Pub. Date: Dec. 7, 2023

(54) SYSTEMS AND METHODS FOR USE IN HANDLING COMPONENTS

(71) Applicant: Electro Scientific Industries, Inc, Beaverton, OR (US)

(72) Inventors: Yonghang FU, Beaverton, OR (US); Gene MIRRO, Kalama, WA (US); Juan HINOJOS, Beaverton, OR (US); Aaron HUMPHREY, Beaverton, OR (US); Kyle BALL, Prosper, TX (US); Jonathan DANDY, Beaverton, OR (US); Gale STRANEY, Tigard, OR (US); Greg ERWIN, Beaverton, OR (US)

(73) Assignee: Electro Scientific Industries, Inc, Beaverton, OR (US)

(21) Appl. No.: 18/248,971

(22) PCT Filed: Sep. 23, 2021
(86) PCT No.: PCT/US21/51665

§ 371 Date: Apr. 13, 2023

Related U.S. Application Data
(60) Provisional application No. 63/092,203, filed on Oct. 15, 2020.

(51) Int. Cl. G01R 31/64; G01R 31/01; G01R 27/02

(52) U.S. Cl. CPC G01R 31/64; G01R 31/016; G01R 27/025

(57) ABSTRACT

A multilayer ceramic capacitor (MLCC) tester includes a power supply source and a station. The station can include at least one test head having a first contact and a second contact arranged and configured to simultaneously electrically connect to a common MLCC transported to a test site, and arc suppression source circuitry. The arc suppression source circuitry can be electrically connected between an output of the power supply source and the first contact, wherein the arc suppression source circuitry is configured to introduce an impedance to the electrical connection between the MLCC and the power supply source.

### BACKGROUND

### I. Technical Field

Embodiments discussed herein relate to systems and methods for handling electrical components.

### II. Discussion of the Related Art

Capacitors, which store electric charge, are one of the basic building blocks of electronic circuits. In its most basic form, a capacitor comprises two conductive surfaces separated from one another by a small distance, wherein a nonconductive dielectric material lies between the conductive surfaces. The capacitance C of such an arrangement is proportional to KA/d, wherein K is the dielectric constant of the dielectric material, A is the area of the opposing conducting surfaces, and d is the distance between the conducting surfaces. A multilayer ceramic capacitor (MLCC) is a type of capacitor made of alternating layers of electrodes and dielectric material (i.e., a ceramic material). MLCCs are commonly used in electronic circuits (e.g., as bypass capacitors, in filters, op-amp circuits, and the like). MLCC manufacturers typically specify their capacitors in terms of parameters such as capacitance (C), dissipation factor (DF), insulation resistance (IR), and the like. MLCCs are typically tested to ensure that they fall within acceptable limits before they are sold or used.

MLCCs can be tested in a variety of machines. Typically, such machines (also referred to herein as “MLCC testers”) carry an MLCC through a series of stations for performing various functions (e.g., testing, pre-soak, pre-charge, etc.). To enhance throughput, MLCC testers are typically configured to carry multiple MLCCs through each station simultaneously. Accordingly, each station includes multiple test heads, wherein each test head is configured to electrically contact a single MLCC (each test head includes a pair of contacts arranged so as to contact different terminal electrodes of an MLCC) and a set of test heads of a common station are arranged and configured to electrically contact a respective set of MLCCs simultaneously (or at least substantially simultaneously). For example, if a station of a hypothetical MLCC tester has four test heads, then the four test heads will electrically contact four MLCCs simultaneously. Throughput is also enhanced by ensuring that sets of test heads of different stations electrically contact different respective sets of MLCCs simultaneously. For example, if the hypothetical MLCC tester has four stations, then test heads of the four stations will electrically contact sixteen MLCCs substantially simultaneously.

FIG. 2 illustrates a perspective view of a conventional MLCC tester as discussed above, which is also described in U.S. Pat. No. 5,842,579 and incorporated herein by reference. Referring to FIG. 2, in the MLCC tester (identified at reference numeral 2), one or more concentric rings 3 of component seats 4 formed in a carrier plate 5 can be rotated (e.g., by a motor) in a clockwise direction around a turntable hub 6. As the carrier plate 5 turns, component seats 4 pass beneath a loading area 10, into and out of a test head assembly 11 (e.g., having five test head modules 12, only two are shown in FIG. 2), and an ejection manifold 13. In loading area 10, MLCCs 14 (see FIG. 3) are poured into the concentric rings 3 and tumble randomly until they are seated in respective ones of the component seats 4. MLCCs 14 are then rotated into the test head assembly 11 where each MLCC 14 is electrically contacted and parametrically tested. Once MLCCs 14 have been tested, the MLCCs 14 are rotated further to the ejection manifold 13, which ejects MLCCs 14 from their seats 4 by blasts of air from selectively actuated, spatially aligned pneumatic valves (not shown). Ejected MLCCs 14 are preferably directed through ejection tubes 15a into sorting bins 15b.

FIGS. 3 and 4 show the test head assembly 11 shown in FIG. 2 in greater detail. Specifically, FIG. 3 shows a perspective drawing of the test head assembly 11 with less than a full complement of test head modules 12 mounted thereon; and FIG. 4 is a fragmentary sectional view taken along lines 4-4 of FIG. 3, juxtaposed with a fragmentary cross-sectional view of an MLCC 14 seated in the carrier plate 5. With reference to FIGS. 3 and 4, each test head module 12 includes a plurality of test heads. Each test head is provided as a pair of contacts (i.e., an upper contact 16 and a lower contact 18) for electrically contacting opposite ends of an MLCC 14 that has been carried to a test site associated with the test head. Within each test head, a lower contact 18 is positioned on the opposite side of test plate 5 from a corresponding upper contact 16, as indicated in FIG. 4. Thus, test head assembly 11 includes a full complement of test head modules 12 in which the terminals of MLCCs 14 can be contacted simultaneously by the contacts of the test heads therein, thereby simultaneously contact the MLCCs carried into the test head assembly 11.

As will be appreciated in light of the discussion above, as MLCCs are carried through the MLCC tester, electrical connections between MLCCs and test heads are repeatedly and simultaneously made and unmade. In operating the MLCC tester in this fashion, there is a possibility that adverse effects can occur, such as unintended interference due to radiated or conducted emissions, repeated expulsion of contact material from the test heads (pitting in the test head contact), or transient waves propagating from circuitry connected to one test head into circuitry connected to neighboring test heads. These adverse effects can result in erratic behavior of the MLCC tester, accelerated degradation of test head contacts, damage to connecting components, increased necessity to repair, refurbish or replace test head contacts or other components, and increased MLCC tester down-time.

### SUMMARY

One embodiment of the present invention can be characterized as a multilayer ceramic capacitor (MLCC) tester that includes a power supply source and a station. The station can include at least one test head having a first contact and a second contact arranged and configured to simultaneously electrically connect to a common MLCC transported to a test site, and arc suppression source circuitry. The arc suppression source circuitry can be electrically connected between an output of the power supply source and the first contact, wherein the arc suppression source circuitry is configured to introduce an impedance to the electrical connection between the MLCC and the power supply source.

Another embodiment of the present invention can be characterized as a multilayer ceramic capacitor (MLCC) tester that includes a station having at least one test head with a first contact and a second contact arranged and configured to simultaneously electrically connect to a common MLCC transported to a test site, station circuitry operative to facilitate testing of the MLCC transported to the test site and arc suppression load circuitry electrically connected between the station circuitry and the second contact. The arc suppression load circuitry can be configured to introduce an impedance to the electrical connection between the MLCC and the station circuitry.

### BRIEF DESCRIPTION OF THE FIGURES

FIG. 1 schematically illustrates components associated with a station of an MLCC tester, according to some embodiments of the present invention.

FIG. 2 illustrates a perspective view of a conventional MLCC tester.

FIGS. 3 and 4 show the test head assembly of the MLCC tester shown in FIG. 2 in greater detail.

### DETAILED DESCRIPTION

Example embodiments are described herein with reference to the accompanying drawings. Unless otherwise expressly stated, in the drawings the sizes, positions, etc., of components, features, elements, etc., as well as any distances therebetween, are not necessarily to scale, but are exaggerated for clarity. In the drawings, like numbers or terms refer to like elements throughout. Thus, the same or similar numbers may be described with reference to other drawings even if they are neither mentioned nor described in the corresponding drawing. Also, even elements that are not denoted by reference numbers may be described with reference to other drawings.

The terminology used herein is for the purpose of describing particular example embodiments only and is not intended to be limiting. Unless otherwise defined, all terms (including technical and scientific terms) used herein have the same meaning as commonly understood by one of ordinary skill in the art. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another. For example, one node could be termed a “first node” and similarly, another node could be termed a “second node”, or vice versa.

Unless indicated otherwise, the term “about,” “thereabout,” “approximately,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Spatially relative terms, such as “below,” “beneath,” “lower,” “above,” and “upper,” and the like, may be used herein for ease of description to describe one element or feature's relationship to another element or feature, as illustrated in the FIGS. It should be recognized that the spatially relative terms are intended to encompass different orientations in addition to the orientation depicted in the FIGS. For example, if an object in the FIGS. is turned over, elements described as “below” or “beneath” other elements or features would then be oriented “above” the other elements or features. Thus, the exemplary term “below” can encompass both an orientation of above and below. An object may be otherwise oriented (e.g., rotated 90 degrees or at other orientations) and the spatially relative descriptors used herein may be interpreted accordingly.

The section headings used herein are for organizational purposes only and, unless explicitly stated otherwise, are not to be construed as limiting the subject matter described. It will be appreciated that many different forms, embodiments and combinations are possible without deviating from the spirit and teachings of this disclosure and so this disclosure should not be construed as limited to the example embodiments set forth herein. Rather, these examples and embodiments are provided so that this disclosure will be thorough and complete, and will convey the scope of the disclosure to those skilled in the art.

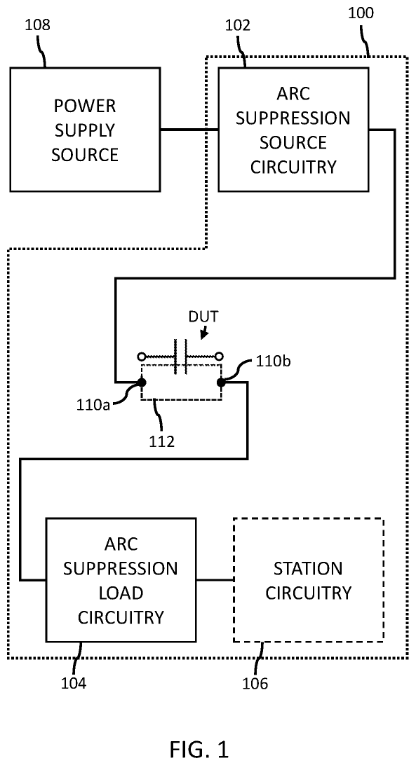

FIG. 1 schematically illustrates components associated with a station of an MLCC tester, according to some embodiments of the present invention.

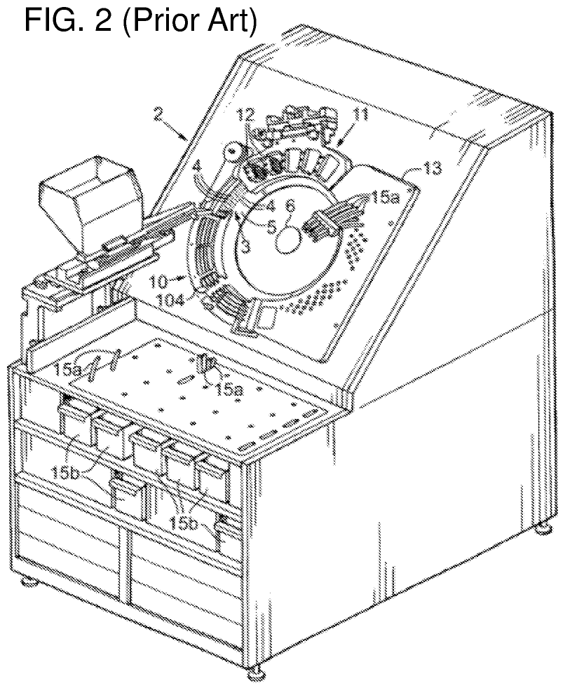

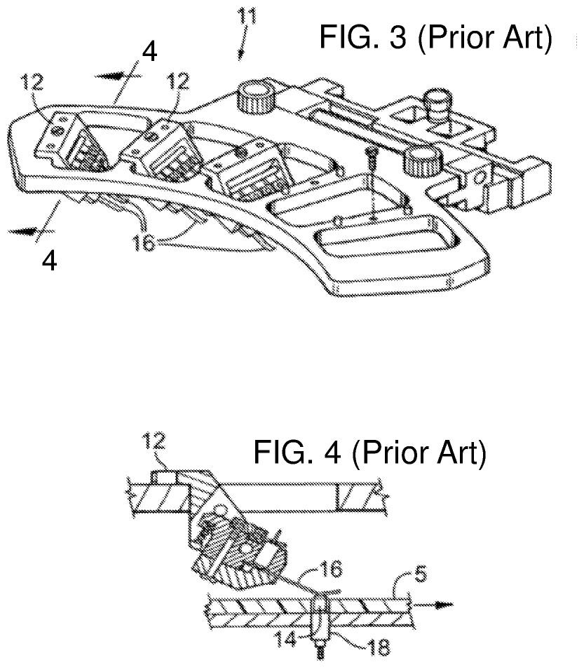

Referring to FIG. 1, a station of an MLCC tester (e.g., an MLCC tester similar to that described above with respect to FIGS. 2-4), is generally shown at 100 and, according to embodiments of the present invention described herein, can include arc suppression source circuitry 102, arc suppression load circuitry 104 and, optionally, station circuitry 106. An input of the arc suppression source circuitry 102 is electrically connected to an output of a power supply source 108. If the station circuitry 106 is included, an input of the station circuitry 106 is electrically connected to an output of the arc suppression load circuitry 104.

Generally, the station circuitry 106 is operative to facilitate testing of an MLCC (e.g., in terms of capacitance, dissipation factor, insulation resistance, etc., of the MLCC). The station 100 will not include station circuitry 106 if the station is a station such as a pre-soak or pre-charge station, both of which are known in the art. The power supply source 108 is operative to provide an electric potential (e.g., at a voltage ranging from less than 1V to 1 kV or more) to the MLCC carried to the station 100. Additional description of the suppression source circuitry 102 and arc suppression load circuitry 104 will be provided further in paragraphs below. Although FIG. 1 illustrates a single station 100 connected to the power supply source 108, it will be appreciated that the MLCC tester may include any number of stations 100 (e.g., 4, 10, 20, 30, 50, etc., or between any of these values), and that one or more (or all) stations 100 may be connected to the same power supply source 108, or to different power supply sources.

The station 100 can also include a pair of contacts, such as a source-side contact 110a and a load-side contact 110b. Together, the pair of contacts can constitute a test head of the station 100. The source-side contact 110a is electrically connected to an output of the arc suppression source circuitry 102 and the load-side contact 110b is electrically connected to an input of the arc suppression load circuitry 104. The source-side contact 110a and load-side contact 110b are arranged such that, when an MLCC to be tested (also referred to herein, and labeled in FIG. 1, as a “DUT”) has been carried to the station 100, each of the source-side contact 110a and load-side contact 110b electrically connect to different terminals of the DUT. For purposes of facilitating discussion, a DUT is deemed to have been carried to the station 100 when the DUT has been moved to a test site of the test head (i.e., when the DUT is positioned completely within region 112, also schematically illustrated in FIG. 1, so that terminals of the DUT contact a respective source-side contact 110a and load-side contact 110b).

Generally, an MLCC to be tested may be provided as any type of two-terminal MLCC (i.e., an MLCC having two terminals) or multi-terminal MLCC (i.e., an MLCC having more than two terminals). Thus, although FIG. 1 schematically illustrates the station 100 as including only two contacts (i.e., a single source-side contact 110a and a single load-side contact 110b) arranged on opposite sides of the test site 112, it will be appreciated that more than one source-side contact 110a and/or single load-side contact 110b may be provided and arranged in any suitable manner depending upon the type of MLCC that is to be tested at the station 100. It will also be appreciated that the arrangement of the contacts may vary depending upon the type of MLCC that is to be tested at the station 100.

It will be appreciated that the DUT can be carried to the station 100, and away from the station 100, by any suitable mechanism known in the art. For example, any suitable carrier plate known in the art (e.g., as described above with respect to FIGS. 2 and 4) may be used to simultaneously carry multiple DUTs. Generally, the carrier plate is mechanically connected to an actuator (e.g., a stepper motor), that moves the carrier plate so that DUTs carried by the carrier plate can be carried to the station 100 (e.g., so that some function can be performed on the DUT at the station 100 using, for example, the station circuitry 106) and moved away from the station 100 (e.g., after a function has been performed on the DUT).

When the DUT has been moved to the test site of the test head, the DUT is electrically connected to the source-side contact 110a and the load-side contact 110b. Accordingly, the DUT may be electrically connected to the power supply source 108 (e.g., to receive a voltage from the power supply source 108) and to the station circuitry 106. In this case, the arc suppression source circuitry 102 may optionally include one or more circuit elements (e.g., one or more resistors, inductors, capacitors, or any combination thereof) electrically connected to the source-side contact 110a to provide a desirable impedance to the electrical connection between the DUT and the power supply source 108. Likewise, the arc suppression load circuitry 104 may optionally include one or more circuit elements (e.g., one or more resistors, inductors, capacitors, or any combination thereof) electrically connected to the load-side contact 110b to provide a desirable impedance to the electrical connection between the DUT and the station circuitry 106. In this case, the impedance-providing circuit elements of the arc suppression source circuitry 102 are located in close proximity to the source-side contact 110a and the impedance-providing circuit elements of the arc suppression load circuitry 104 are located in close proximity to the load-side contact 110b. As used herein, an impedance-providing circuit element is within close proximity of a contact (i.e., either the source-side contact 110a or the load-side contact 110b) if the impedance-providing circuit element is within six inches (or thereabout) or less of the contact. That is, an impedance-providing circuit element is within close proximity of a contact (i.e., either the source-side contact 110a or the load-side contact 110b) if the electrical length of a wire (or other conductor) electrically connecting the impedance-providing circuit element to the contact is six inches (or thereabout) or less. Adding impedance in close proximity to either side of the test site of the test head can help to reduce stray capacitance between the DUT and various components of the station 100 in which the test head is located, thereby reducing the energy available to cause the deleterious effects mentioned above.

In one embodiment, the arc suppression source circuitry 102 may include a switch (also referred to herein as an “isolation switch”) and a switch-control circuit operatively connected to the isolation switch. Generally, the isolation switch is arranged and operative to electrically connect or disconnect the source-side contact 110a to the power supply source 108 in a selective manner (i.e., in response to one or more signals output by the switch-control circuit). In this case, the isolation switch can be provided as a solid-state relay such as an optical relay, a MOSFET relay, an inductor coupler, an electromechanical relay, or the like or any combination thereof. If the arc suppression source circuitry 102 includes one or more of the aforementioned circuit elements for providing impedance, then the isolation switch should be located between such elements and the output of the power supply source 108. Further, if the arc suppression source circuitry 102 includes one or more of the aforementioned circuit elements for providing impedance, then the isolation switch should be located in close proximity to such elements in order to reduce stray capacitance between the DUT and various components of the station 100.

Generally, the switch-control circuit is operative to cause the isolation switch to electrically connect the source-side contact 110a to the power supply source 108 only when the DUT is carried to the station 100. Thus, the switch-control circuit is operative to cause the isolation switch to electrically disconnect the source-side contact 110a from the power supply source 108 to ensure that the source-side contact 110a is electrically disconnected from the power supply source 108 when the DUT is not at the station 100 (i.e., when the DUT is being carried to or from the station 100). By electrically connecting the source-side contact 110a to the power supply source 108 only when the DUT is present at the station 100, the deleterious effects mentioned above can be eliminated or otherwise reduced.

Depending on one or more factors such as the configuration of the source-side contact 110a, the velocity with which the DUT is travelling when carried to the station 100, etc., the inventors have detected that contact between the source-side contact 110a and a terminal of the DUT can be intermittent for an initial period of time (also referred to herein as a “settle period”) after the DUT has been carried to the station 100. Accordingly, the switch-control circuit can be further operative to delay operation of the isolation switch to electrically connect the source-side contact 110a to the power supply source 108 after the settle period has elapsed.

In one embodiment, the station 100 may include one or more diodes (not shown) electrically connected between the arc suppression source circuitry 102 isolation switch and the source-side contact 110a. Generally, the one or more diodes are configured to prevent current from back-flowing from a DUT at the station 100 to a DUT at a station (not shown) adjacent to the illustrated station 100.

Provided as described above, embodiments of the present invention can be implemented to: reduce radiated and conducted emissions, reduce wear on test head contacts, increase life of components and minimize waste and minimize down time of the MLCC tester. As mentioned above, the MLCC tester may include multiple stations 100, some of which may be configured to perform the same functions on different DUTs, and some of which may be configured to perform different functions on a DUT. When different stations 100 are configured to perform different functions on a DUT, it will be appreciated that the station circuitry 106 of different stations 100 can be differently configured. Optionally, the arc suppression source circuitry 102 may be differently configured as between stations 100 configured to perform different functions on a DUT. For example, source suppression circuitry 102 in a station 100 configured to perform a pre-soak function on a DUT may include the one or more diodes discussed above, but source suppression circuitry 102 in another station 100 configured to perform a different function need not (but still may) include the one or more diodes. In another example, source suppression circuitry 102 in a station 100 configured to perform an insulation resistance testing function on a DUT may include the isolation switch discussed above, but source suppression circuitry 102 in another station 100 configured to perform a different function need not (but still may) include the isolation switch.

The foregoing is illustrative of embodiments and examples of the invention, and is not to be construed as limiting thereof. Although a few specific embodiments and examples have been described with reference to the drawings, those skilled in the art will readily appreciate that many modifications to the disclosed embodiments and examples, as well as other embodiments, are possible without materially departing from the novel teachings and advantages of the invention. Accordingly, all such modifications are intended to be included within the scope of the invention as defined in the claims. For example, skilled persons will appreciate that the subject matter of any sentence, paragraph, example or embodiment can be combined with subject matter of some or all of the other sentences, paragraphs, examples or embodiments, except where such combinations are mutually exclusive. The scope of the present invention should, therefore, be determined by the following claims, with equivalents of the claims to be included therein.

1. A multilayer ceramic capacitor (MLCC) tester, comprising:
a power supply source; and
a station including:
at least one test head having a first contact and a second contact, the first contact and second contact arranged and configured to simultaneously electrically connect to a common MLCC transported to a test site; and
arc suppression source circuitry electrically connected between an output of the power supply source and the first contact, wherein the arc suppression source circuitry is configured to introduce an impedance to the electrical connection between the MLCC and the power supply source, wherein the arc suppression source circuitry includes:
a switch operable to selectively electrically connect and disconnect the power supply source and first contact; and
switch-control circuitry connected to the switch and configured to control an operation of the switch, wherein the switch-control circuitry is configured to control the switch to electrically connect the power supply and the first contact electrically only after a predetermined amount of time has elapsed after the MLCC is transported to the test site.

2. The MLCC tester of claim 1, wherein the power supply source is operative to provide an electric potential, at a voltage of at least 1 kV, to the MLCC transported to the test site.

3. The MLCC tester of claim 1, wherein the first contact and the second contact are arranged at opposite sides of the test site.

4. The MLCC tester of claim 1, wherein the arc suppression source circuitry includes at least one circuit element selected from the group consisting of a resistor, inductor, and capacitor.

5. The MLCC tester of claim 4, wherein the at least one circuit element is within 6 inches or less of the first contact.

6. (canceled)

7. The MLCC tester of claim 1, wherein the switch includes an optical relay.

8. (canceled)

9. The MLCC tester of claim 1, further comprising at least one diode electrically connected between the isolation switch and the first contact, wherein the at least one diode is configured to prevent current from back-flowing away from the MLCC.

10. The MLCC tester of claim 1, further comprising a carrier plate operative to transport the MLCC to the test site.

11. The MLCC tester of claim 1, wherein the station does not include circuitry operative to facilitate testing of the MLCC transported to the test site.

12. The MLCC tester of claim 1, further comprising:
station circuitry operative to facilitate testing of the MLCC transported to the test site; and
arc suppression load circuitry electrically connected between the station circuitry and the second contact, wherein the arc suppression load circuitry is configured to introduce an impedance to the electrical connection between the MLCC and the station circuitry.

13. The MLCC tester of claim 12, wherein the station circuitry is operative to test at least one selected from the group consisting of a capacitance, dissipation factor, and insulation resistance of the MLCC transported to the test site.

14. The MLCC tester of claim 12, wherein the arc suppression load circuitry includes at least one circuit element selected from the group consisting of a resistor, inductor, and capacitor.

15. The MLCC tester of claim 14, wherein the at least one circuit element is within 6 inches or less of the first contact.

16. The MLCC tester of claim 12, further comprising at least one diode electrically connected between the isolation switch and the first contact, wherein the at least one diode is configured to prevent current from back-flowing away from the MLCC.

17. A multilayer ceramic capacitor (MLCC) tester, comprising:
a station including:
at least one test head having a first contact and a second contact, the first contact and second contact arranged and configured to simultaneously electrically connect to a common MLCC transported to a test site;
station circuitry operative to facilitate testing of the MLCC transported to the test site; and
arc suppression load circuitry electrically connected between the station circuitry and the second contact, wherein the arc suppression load circuitry is configured to introduce an impedance to the electrical connection between the MLCC and the station circuitry, wherein the arc suppression load circuitry includes:
a switch operable to selectively electrically connect and disconnect the station circuitry and second contact; and
switch-control circuitry connected to the switch and configured to control an operation of the switch, wherein the switch-control circuitry is configured to control the switch to electrically connect the station circuitry and the second contact electrically only after a predetermined amount of time has elapsed after the MLCC is transported to the test site.

18. The MLCC tester of claim 17, wherein the station circuitry is operative to test at least one selected from the group consisting of a capacitance, dissipation factor, and insulation resistance of the MLCC transported to the test site.

19. The MLCC tester of claim 17, wherein the arc suppression load circuitry includes at least one circuit element selected from the group consisting of a resistor, inductor, and capacitor.

20. The MLCC tester of claim 19, wherein the at least one circuit element is within 6 inches or less of the first contact.

21. The MLCC tester of claim 1, wherein the switch includes at least one selected from the group consisting of a MOSFET relay, an inductor coupler and an electromechanical relay.

22. The MLCC tester of claim 1, wherein the station is a pre-soak station.

23. The MLCC tester of claim 1, wherein the power supply source is operative to provide an electric potential, at a voltage of up to 1 kV, to the MLCC transported to the test site.
